(19) United States
(12) Patent Application Publication
(10) Pub. No.: US 2011/0220198 A1
(43) Pub. Date: Sep. 15, 2011

(54) Method and Device Utilizing Strained AZO Layer and Interfacial Fermi Level Pinning in Bifacial Thin Film PV Cells

(75) Inventors: Ashish Tandon, Sunnyvale, CA (US); Fred Mikulec, San Jose, CA (US)

(73) Assignee: Stion Corporation, San Jose, CA (US)

(21) Appl. No.: 13/049,190

(22) Filed: Mar. 16, 2011

Related U.S. Application Data
(60) Provisional application No. 61/319,557, filed on Mar. 31, 2010.

(51) Int. Cl. H01L 31/0224; H01L 31/18

(52) U.S. Cl. 136/256; 438/85; 257/E31.126

(57) ABSTRACT

A method for forming a bifacial thin film photovoltaic cell includes providing a glass substrate having a surface region covered by an intermediate layer and forming a thin film photovoltaic cell on the surface region. Additionally, the thin film photovoltaic cell includes an anode overlying the intermediate layer, an absorber over the anode, and a window layer and cathode over the absorber mediated by a buffer layer. The anode comprises an aluminum doped zinc oxide (AZO) layer forming a first interface with the intermediate layer and a second interface with the absorber. The AZO layer is configured to induce Fermi level pinning at the first interface and a strain field from the first interface to the second interface.

### CROSS-REFERENCE TO RELATED APPLICATIONS

This application claims priority to U.S. Provisional Application No. 61/319,557, filed Mar. 31, 2010, commonly assigned, and hereby incorporated by reference in its entirety herein for all purpose.

### BACKGROUND OF THE INVENTION

The present invention relates generally to photovoltaic device and manufacturing method. More particularly, the present invention provides a method and device structure for a bifacial thin film photovoltaic cell. Embodiments of the present invention include a method for forming a bifacial thin film photovoltaic device utilizing strain field in anode and Fermi level pinning to modify internal electric field for enhancing cell efficiency. One application for the invention is a device utilizing a strained AZO layer as an interface between a PV absorber and an anode layer for enhancing hole collection.

From the beginning of time, mankind has been challenged to find ways of harnessing energy. Energy comes in forms such as petrochemical, hydroelectric, nuclear, wind, biomass, solar, wood and coal. Over the past century, modern civilization has relied upon petrochemical energy as an important energy source. Petrochemical energy includes gas and oil. This includes lighter forms such as butane and propane, commonly used to heat homes and serve as fuel for cooking, as well as gasoline, diesel, and jet fuel, commonly used for transportation purposes. Heavier forms of petrochemicals can also be used to heat homes. Unfortunately, the supply of petrochemical fuel is limited and essentially fixed based upon the amount available on earth. As more people use petroleum products in growing amounts, it is rapidly becoming a scarce resource.

Environmentally clean and renewable energy is desirable. An example of a clean source of energy is hydroelectric power. Hydroelectric power is derived from electric generators driven by the flow of water produced by dams. Clean and renewable sources of energy also include wind, waves, biomass, and the like. Windmills convert wind energy into more useful forms of energy such as electricity. Still other types of clean energy include solar energy.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used. As an example, one type of solar cell uses crystalline materials, which are derived from semiconductor material ingots. These crystalline materials can be used to fabricate optoelectronic devices that include photovoltaic and photodiode devices that convert electromagnetic radiation to electrical power. However, crystalline materials are often costly and difficult to make on a large scale. Other types of solar cells use “thin film” technology to form a thin film of photosensitive material to be used to convert electromagnetic radiation into electrical power. Similar limitations exist with the use of thin film technology in making solar cells. That is, efficiencies are often poor. Additionally, film reliability is often poor and cannot be used for extensive periods of time in conventional environmental applications. Often, thin films are difficult to mechanically integrate with each other. These and other limitations of these conventional technologies can be found throughout the present specification and more particularly below.

As an effort to improve cell efficiency of the thin film solar cell, processes for improving relative band alignment at the heterojunctions of the cell play important roles in enhancing final performance of the solar cells. There are various manufacturing challenges in choosing proper materials and structures for forming the thin film PV cell junction interfaces with proper electric field strength and direction. In particular, the band lineup between an absorber and an anode or between a window layer and a cathode through respective interfaces affects the carrier collection efficiency and build-in voltage of the cells. While conventional techniques in the past have addressed some of these issues, they are often inadequate in various situations. Therefore, it is desirable to have improved method and structure for designing the cell junction interface for the thin film photovoltaic devices.

### BRIEF SUMMARY OF THE INVENTION

This invention provides a method for forming a bifacial thin film photovoltaic cell. The method includes providing a glass substrate having a surface region covered by an intermediate layer and forming a thin film photovoltaic cell on the surface region. The thin film photovoltaic cell includes an anode overlying the intermediate layer, and an absorber layer over the anode. Furthermore, the cell includes a window layer and cathode over the absorber mediated by a buffer layer. The anode includes an aluminum doped zinc oxide (AZO) layer forming a first interface with the intermediate layer and a second interface with the absorber. The AZO layer is configured to induce Fermi level pinning at the first interface and a strain field from the first interface to the second interface.

In an alternative embodiment of the present invention, a thin film solar device utilizing a strained AZO layer for anode-absorber interface is provided. The device includes an optical transparent substrate and an intermediate layer overlying the transparent substrate. Additionally, the device includes an anode layer comprising an aluminum doped zinc oxide (AZO) layer forming a first interface with the intermediate layer. The device further includes an absorber comprising copper indium gallium diselenide with p-type dopant forming a second interface with the AZO layer. Furthermore, the device includes a buffer layer followed by a window layer overlying the absorber. Moreover, the device includes a cathode layer overlying the window layer. In a specific embodiment, the AZO layer utilized by the device induces a strain field in the anode layer and Fermi level pinning at the first interface for changing an internal electric field at the second interface.

Some embodiments of the present invention provide a method for modifying an internal electric field around anode-absorber interface using a combination of strain in anode and Fermi level pinning at the interface to diminish electric field strength or even flipping the internal electric field direction. The reduced internal electric field strength lowers the barrier for easier tunneling through by the carrier holes from the absorber to the anode. The flipped direction of the internal electric field at the interface between the absorber and the back electrode directly aids the hole collection by the n+-type anode from the p-type absorber.

An intermediate layer is placed between an AZO layer and the surface region of the substrate. The lattice mismatch between the AZO layer and the intermediate layer causes a strain in the anode, which changes the electric field at the interface between the anode and the absorber. At the interfaces between AZO layer and the intermediate layer or between AZO layer and the absorber, the electron band is modified by surface states and aligned via Fermi level pinning across the interfaces. Both the strain in the anode and Fermi level pinning can cause the internal electric field at the back electrode to diminish or even flip direction, which aid in the collection of holes at the back contact and thus improve cell efficiency.

### BRIEF DESCRIPTION OF THE DRAWINGS

FIG. 1 is a diagram illustrating a thin film photovoltaic cell utilizing an aluminum doped zinc oxide layer at anode-absorber interface;

FIG. 2 is a diagram illustrating an internal electric field across an absorber and its interfaces in a typical bifacial structure;

FIG. 3A is a diagram illustrating heterojunction energy band structure of a bifacial cell;

FIG. 3B is a closer view of the energy band structure at the anode-absorber interface of the bifacial cell;

FIG. 4 is a diagram illustrating a strained film with an interface of two materials having mismatched lattice spacing;

FIG. 5 is a diagram of the modified internal electric field at anode-absorber interface by combined effect of strain in anode and interfacial Fermi level pinning according to an embodiment of the present invention;

FIG. 6 is a diagram illustrating a cross-sectional SEM image of sputtered AZO layer with columnar morphology; and

FIG. 7 is a diagram illustrating an X-ray diffraction pattern of sputtered zinc oxide layer with wurtzite structure showing a unit cell in native and stressed states.

### DETAILED DESCRIPTION OF THE PREFERRED EMBODIMENTS

Embodiments of the present invention provide a method and device structure for a bifacial thin film photovoltaic cell. They include a method for forming a bifacial thin film photovoltaic device utilizing a strain field in the anode layer and interface Fermi level pinning to modify the internal electric field at the anode-absorber interface, enhancing cell efficiency. A device utilizing an AZO layer as an interface between a PV absorber and an anode layer for enhancing hole collection is provided.

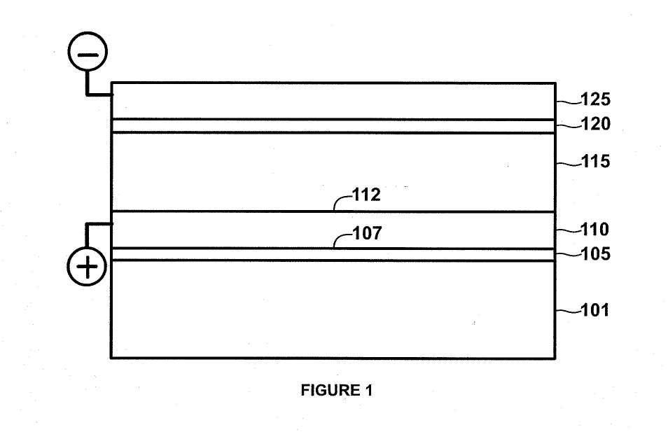

FIG. 1 is a diagram illustrating a thin film photovoltaic cell utilizing an aluminum doped zinc oxide layer at anode-absorber interface according to an embodiment of the present invention. As shown, a thin film photovoltaic (PV) cell 100 is formed on a substrate 101. Typically, for bifacial thin film PV cell a transparent material, e.g. soda lime glass, is selected for the substrate. In an embodiment, an intermediate layer 105 is formed overlying a surface region of the substrate 101. The intermediate layer 105 is a base layer for a back electrode, typically an anode. In a specific embodiment, the intermediate layer 105 can serve as a barrier layer for preventing sodium species from diffusing into the electrode layer from soda lime glass.

In another specific embodiment, the intermediate layer 105 is optically transparent to sunlight for facilitating the absorption from the back side of the cell. The intermediate layer 105 is preferably a transparent oxide layer made by materials selected from flourine doped tin oxide (TFO), indium tin oxide (ITO), and silicon dioxide (SiO₂) or silicon nitride. In another specific embodiment, the intermediate layer 105 can become part of the back electrode of the cell 100 if a conductive material is selected and configured to form an electric contact for the anode of the cell. For example, thin films of transparent conductive oxide and/or metal (such as molybdenum) can be included in the intermediate layer 105. Additionally, the intermediate layer 105 can serve as a structural base layer for controlling strain field in a layer grown overlying itself by setting one side of interface with a lattice constant in a predetermined range. The layer formed on top of it may be formed under strain in a controllable manner due to lattice mismatch.

As shown in FIG. 1, an anode layer 110 is formed overlying the intermediate layer 105. In a specific embodiment, the anode layer 110 is an aluminum doped zinc oxide (AZO) layer, forming at least a first interface 107 between the AZO layer 110 and the intermediate layer 105. Films of aluminum-doped zinc oxide are transparent and electrically conductive. The optical property of AZO is characterized by high transmission in the visible region and useable transmission to IR wavelengths as long as ˜12 μm. The AZO layer 110 can be deposited by sputtering from a target composed of 2-4% Al metal (or in the form of Al₂O₃) incorporated in ZnO. The AZO layer 110 can be deposited by RF or DC magnetron sputtering with target power density at about 3 W/cm² or lower in a vacuum chamber at about 1-10 mtorr pressure range with oxygen and argon gas mixture flowed in. Alternatively, the AZO layer can be formed using MOCVD method. After the formation of the AZO layer on the intermediate layer 105, the aluminum, serving as an n-type dopant, can have an atomic level ranging from 5×10¹⁹ cm⁻³ to 1×10²¹ cm⁻³ in the n⁺ anode. Electrical conductance, measured as bulk resistivity or as sheet resistance, is related to deposition properties and layer thickness.

Referring to FIG. 1, an absorber 115 is formed overlying the AZO layer 110, leading to a formation of at least a second interface 112 between the anode 110 and the absorber 115. The absorber 115 of the cell 100 is a photovoltaic material, typically p-type semiconductor film. In a specific embodiment, the absorber 115 is formed by thermally treating a precursor layer in a gaseous environment. For example, a precursor layer including copper species, indium species, and/or indium-gallium species may be formed on a surface of the substrate using sputtering. In a subsequent reactive thermal treatment process, the precursor layer can be reactively treated in a gaseous environment within the furnace tube containing selenide species, or sulfuride species, and nitrogen species, etc. When the furnace tube is heated, the gaseous selenium reacts with the copper-indium-gallium species in the precursor layer. As a result of the reactive thermal treatment, the precursor layer is transformed to a photovoltaic film stack containing copper indium (gallium) diselenide (CIS/CIGS) compound, which is a p-type semiconductor and serves as an absorber layer for forming photovoltaic cells.

More detail descriptions about the thermal treatment process for forming the CIGS photovoltaic film stack of thin film solar cells can be found in U.S. Patent Application No. 61/178,459 titled “Method and System for Selenization in Fabricating CIGS/CIS Solar Cells” filed on May 14, 2009 by Robert Wieting, commonly assigned to Stion Corporation of San Jose and hereby incorporated by reference. In certain embodiments, the absorber 115 can be made of cadmium tellurium compound semiconductor with a p-type dopant. Of course, there can be other variations, modifications, and alternatives. For example, here the absorber is illustrated as a single junction structure, while it can be alternatively formed or variably repeated in cells with two or more junctions.

Over the absorber 115, the cell 100 includes a window layer 125. In a specific embodiment, a buffer layer 120 can be inserted between the window layer 125 and the absorber 115. The buffer layer 120 is n-type in electric characteristic while the window layer 125 is n+ type in electric characteristic. In an embodiment, the buffer layer 120 can be made of cadmium sulfide compound using chemical bath deposition (CBD) method. In another embodiment, the buffer layer can be made by zinc oxide using MOCVD method. The MOCVD method is used, instead of sputtering, to form the zinc oxide buffer layer so that possible structural damage of the second interface caused by sputtering technique can be substantially reduced. In a preferred embodiment, the window layer 125 is an AZO layer, with a thickness thinner than absorber 115. In certain embodiments, the window layer 125 can be used to form a cathode contact of the solar cell. Alternatively, an additional layer made of boron doped zinc oxide can be added using MOCVD method to form a front electric contact with n⁺ electric characteristic.

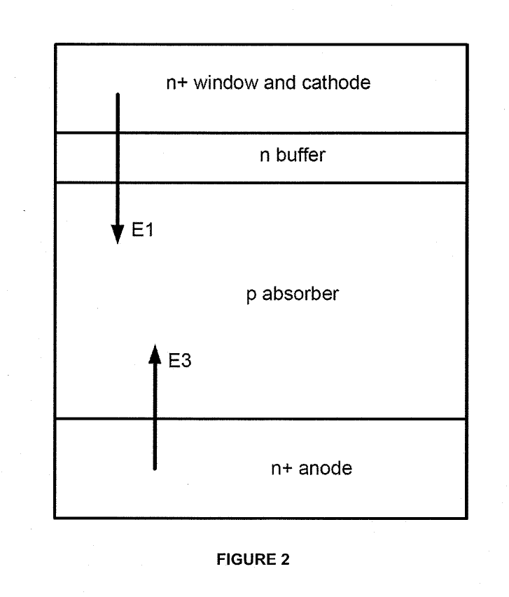

To configure the thin film solar cell, bifacial cell structure has been used with an intention for enhancing photon absorption from both sides of the absorber. FIG. 2 is a simplified diagram illustrating internal electric field across an absorber and its interfaces in a typical bifacial structure. In this structure, both anode and cathode layer are made from AZO material with n+ electric characteristic and a p-type absorber is sandwiched in between. Because of the structural configuration and electrical property under equilibrium conditions, the internal electric field at both interfaces of the absorber may have a direction pointed to the absorber from the electrode contact. As shown in FIG. 2, in particular, the electric field E3 at the back contact points towards the p-type absorber. Such a configuration is not conductive to the collection of holes. In other words, the sign of E3 is against the hole transportation from the absorber to the back contact. Energetically, the strength of the internal electric field relates to a hard energy barrier for the holes to tunnel through.

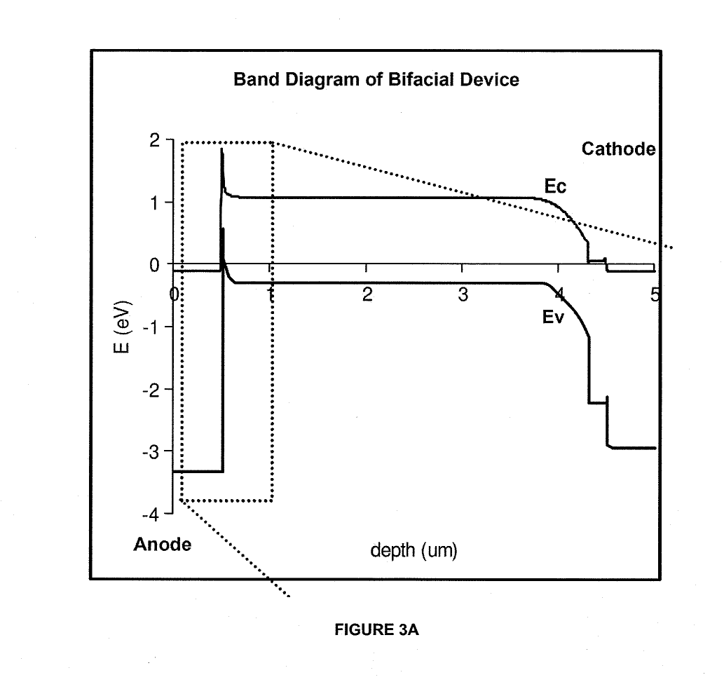

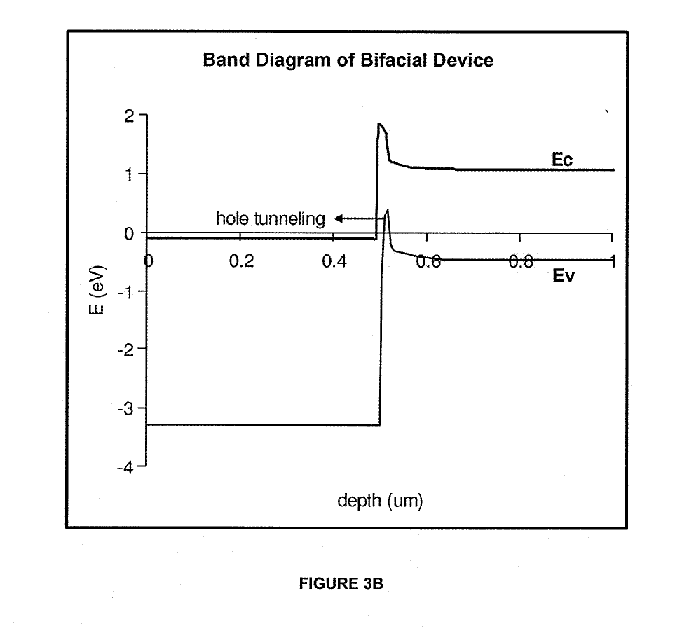

FIG. 3A is a simplified diagram illustrating heterojunction band structure of a bifacial cell. It shows both a valence band Ev and conduction band Ec of a typical bifacial cell structure with n+ transparent oxide as a back contact, an anode contact on the left side and a cathode contact on the right side. FIG. 3B is a closer view of the band structure at the anode-absorber interface of the bifacial cell. As shown, a barrier exists at the anode-absorber interface so that the cell must rely on tunneling currents for collection of carrier holes by the back contact. The holes usually do not have sufficient energy for thermionic emission. The internal electric field here is opposing the tunneling of holes by pointing towards the absorber. Without efficient collection of carrier holes, the solar cell cannot produce sufficient high PV current as a basis for a solar cell with high efficiency. Therefore, there is need to utilize mechanisms for lowering the tunneling barrier by modifying the internal electric field in anode or even changing the sign of the internal electric field at the anode-absorber interface to aid the tunneling current.

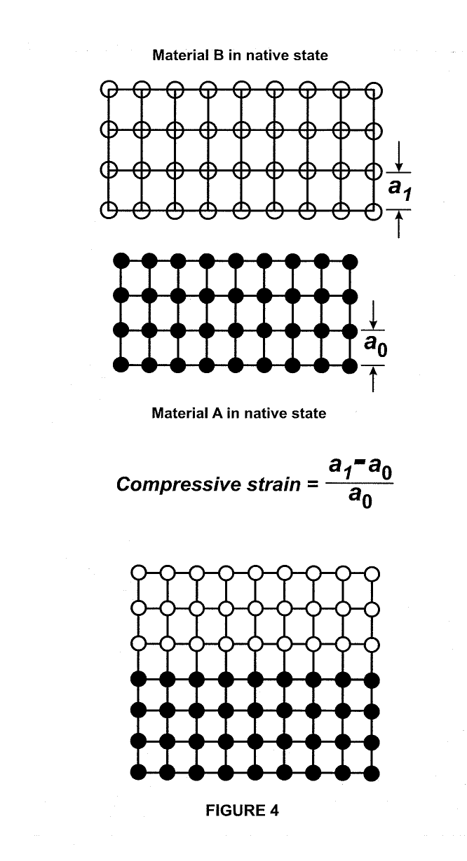

The present invention provides a method of modifying internal electric field using a back electrode structure comprising AZO material overlying an intermediate layer placed firstly on an surface region of a (transparent) substrate. The method includes utilizing lattice mismatch strain to modify the internal electric field across the anode-absorber interface. FIG. 4 is a diagram illustrating a strained film with an interface of two materials having mismatched lattice spacing. As shown, when two materials A and B with different lattice spacing in each native state are placed together, such as by growing a layer of B material on a layer of A material, both layers conform to reach an equilibrium thermodynamic state that reduces the free energy of the A+B system. Material B has a lattice constant a₁ which is greater than a lattice constant a₀ of material A. The material B will be under compressive stress to accommodate smaller lattice of material A, while the latter will be under tensile stress at the same time. The strain is each of two layers, one in compression and one in tension, can be directly related to a value of (a₁−a₀)/a₀.

The properties of thin films under stress are altered from their native unstressed state. For example, energy band alignment, carrier mobility, recombination rate of minority carrier, density of states, piezoelectric fields, etc. are changed by the strain within the film. By properly configuring the interface structures, the alternation of the above physical properties can be controlled as a function of the interface structures. This offers a basis for build a multi-layer thin film based photovoltaic junction that caters to desired solar device performance requirement. In particular, the carrier collection efficiency of thin film based solar cell can be enhanced by utilizing the strain in the anode to reduce the tunneling barrier for collecting holes from the absorber, according to an embodiment of the present invention. As shown in FIG. 3, an energy barrier determined by conduction band offset exits between anode and absorber. A desired band offset can be ranged from 0.1 eV to 0.3 eV. The relative band alignment between the various materials in the cell determine the nature of an IV curve and hence the cell efficiency factor. Band discontinuities, especially those in the conduction band lead to irregularities or “kinks” in the cell's IV curve. The relative band alignment at the heterojunction in thin film based solar cells is a major factor in determining the final performance. The field at the junction is responsible for the separation of electrons and holes in the space charge region. Carriers generated in the quasi-neutral regions diffuse to the edge of the space charge regions where they drift under the influence of the internal electric field. When the strain in anode layer is changed and so is the internal electric field, the band alignment at the interface can be tuned in favor of aiding the collection of carrier holes. For example, the internal electric field may be reduced so that the energy barrier for hole tunneling can be substantially diminished. Or, the internal electric field is flipped to an opposite direction towards the anode, directly assisting the carrier current.

The other effect that influences the choice of the materials and structures of the anode-absorber interface include a phenomena of Fermi-level pinning at the interface. The pinned surface can lower the diode and hence photovoltaic response of the cell, improving cell performance. Most semiconductors have broken dangling bonds at the surface that are chemically active. The non-symmetrical break in the crystal potential leads to the formation of mid-gap defect-like energy states that act as recombination centers. These surface states can be the determining factor in the position of the Fermi level (instead of the intrinsic carrier levels). The extent to which the Fermi level pins is determined by the density of such surface states, their capture cross sections and their position within the energy band. During the sequential formation of the thin film stack, the surface states substantially retained at the interfaces as upper layers overlay the under layer. Pinning of Fermi level by the interface states “freezes” the bands in the space charge region across the interface, i.e. it predetermines the band alignment and bending from the absorber to the anode regardless of the doping level of the either layer across the interface.

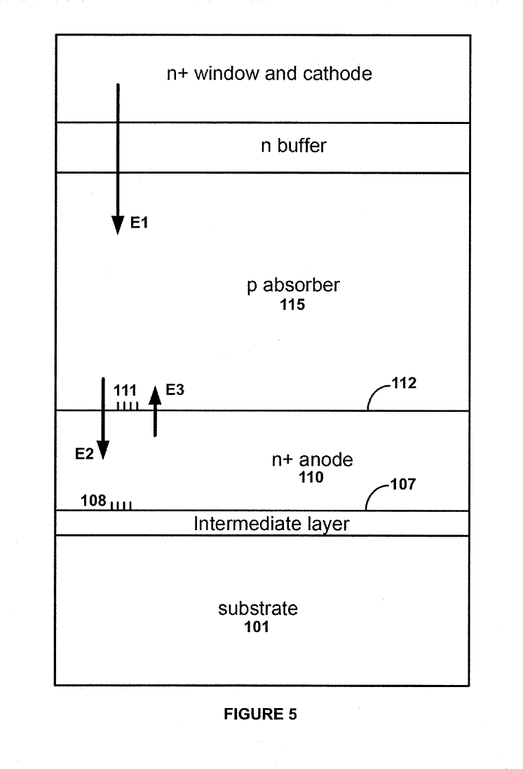

FIG. 5 is a diagram of the modified internal electric field at anode-absorber interface by combined effect of strain in anode and interfacial Fermi level pinning according to one embodiment of the invention. As shown, an intermediate layer 105 is placed on a substrate 101 before a formation of an anode layer 110 and followed by an absorber layer 115. In certain embodiments, the intermediate layer 105 plays at least two roles for improving the thin film based bifacial solar cell by modifying the internal electric field therein. It creates the first interface 107 between the n+ semiconductor AZO layer 110 and the intermediate layer 105. At the first interface broken chemical bonds of either of the two layers and interface atomic reconstructions lead to formation of interface states which directly result in the Fermi level pinning effect. Additionally, the Fermi level pinning 108 at the first interface 107 is coupling with the Fermi level pinning 111 at a second interface 112 between the AZO layer 110 and the absorber 115 formed thereafter. As the results of the Fermi level pinning 108 and 111 at the interfaces, an energy barrier for hole tunneling can be tuned in favor for enhancing carrier collection efficiency while reducing photo-induced electron-hole recombination.

Secondly, the intermediate layer 105 formed over the glass substrate 101 sets a base layer for forming AZO layer 110, which can be utilized for better controlling lattice mismatch strain in the subsequently formed AZO layer 110 than directly placing the AZO layer over the glass substrate 101. In an embodiment, the material and thickness of the intermediate layer 105 are used as engineering parameters for tuning the strain field within the AZO layer 110. For example, an intermediate layer may include a material with an (average) lattice constant smaller than that of the AZO layer so that the overlying AZO layer is controlled to be in compression. The intermediate layer may include a material with a greater lattice constant so that the strain field in the overlying AZO layer may be turned into a tensile characteristic. The AZO layer can be formed by a sputtering technique using a zinc or zinc oxide target doped with aluminum. Alternatively, the AZO layer can be formed using an MOCVD method. The AZO layer 110 may include a heavily doped Al species ranging from 5×10¹⁹ cm⁻³ to 1×10²¹ cm⁻³.

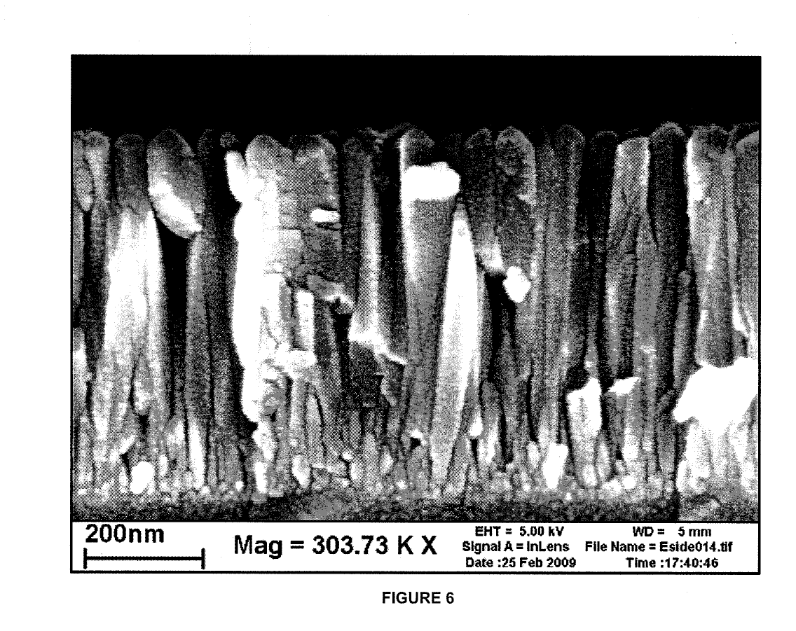

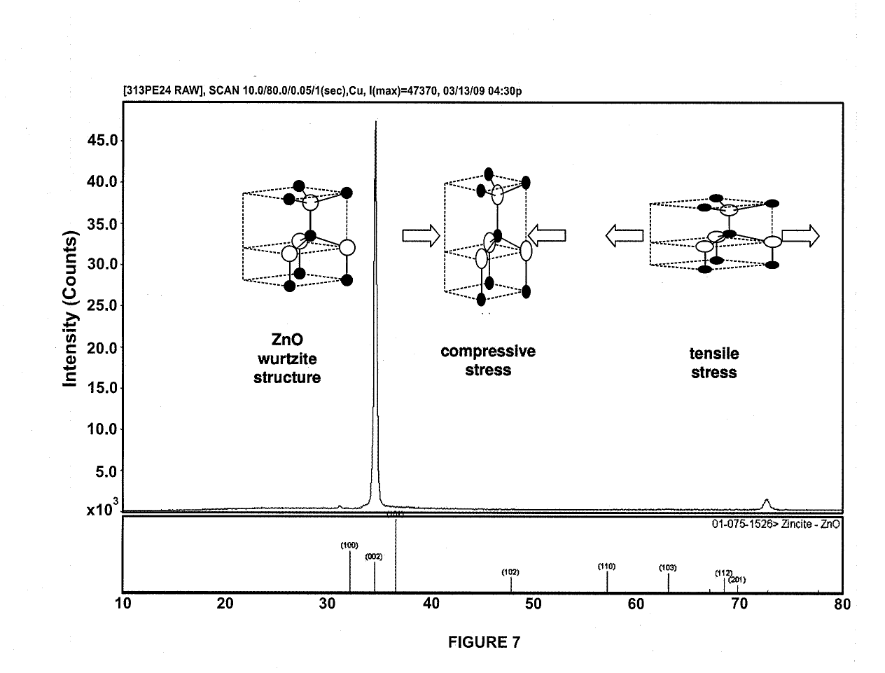

FIG. 6 is a cross-sectional SEM image of sputtered AZO layer with oriented columnar morphology showing that the zinc oxide film formed by sputtering is characterized by a columnar morphology. The orientation of the columnar structures is substantially perpendicular to the substrate throughout the whole film thickness of about 600 nm. In terms of atomic structure, zinc oxide (ZnO) or zinc oxide doped with aluminum (ZnO:Al) is a wurtzite structure (see inset in FIG. 7), having a unit cell with an elongated c-axis perpendicular to a zinc atom layer and an oxygen atom layer in (100) plane. FIG. 7 also shows an X-ray diffraction plot with a dominate [002] peak clearly indicating the columnar orientation along a c-axis. For the ZnO or AZO layer 110 formed on the intermediate layer 105, the c-axis is perpendicular to the first interface 107. Oriented zinc oxide film displays the largest piezoelectric effect, which becomes an advantageous property that can be utilized for controlling the strain induced modification of the internal electric field in the film. The inset of FIG. 7 also shows the unit cell of Zinc Oxide under stress, one in compression and one in tension. As seen, the unit cell is either shrunk or expanded only in the (100) plane and correspondingly extended or retracted in c-axis direction since the c-axis is perpendicular to the interface 107. Therefore the mismatch strain in the ZnO or AZO layer directly realign its atomic distances in unit cell and modify its intrinsic piezoelectric property, subsequently causing an alteration of the internal electric field in AZO layer and through an second interface to upper film such as an absorber layer overlying the AZO layer.

Referring to FIG. 5, in a specific embodiment a combination of strain in the anode 110 induced by lattice mismatch between the anode layer 110 and the intermediate layer 105 below and Fermi level pinning at the first interface 107 of the two above layers causes the internal electric field at the second interface 112 between the anode 110 and absorber 115 to diminish. In an embodiment, the internal electric field E3 across the second interface 107 is reduced in strength by the combination effect of the strain and Fermi level pinning. In another embodiment, the internal electric field E2 across the second interface 107 is flipped sign to turn its direction towards the anode instead of pointing to the absorber. These can substantially alter the tunneling barrier for holes to pass from the absorber to the AZO layer and/or directly assist hole current to enhance rate of collection of holes by the back electrode contact. As the result of this combined effect, the thin film based photovoltaic cell can have a much improved photon-electron conversion efficiency which translates to improved solar module efficiency.

In an alternative embodiment, the internal electric field of anode layer can be altered by changing relative Zn and Oxygen composition near the second interface within the AZO layer. For example, when forming the zinc oxide or specifically AZO layer, the oxygen content in the sputtering work gas can be reduced or increased so that the sputtering formed ZnO or ZnO:Al can be Zn-rich or O-rich. In atomic level, the Zn atoms in Zn atom plane can be replaced by excessive Oxygen or the other way around. This can change the intrinsic strain, piezoelectric property, interface energy states and Fermi level pinning, and ultimately the internal electric field.

While the present invention has been described using specific embodiments, it should be understood that various changes, modifications, and variations to the method utilized in the present invention may be effected without departing from the spirit and scope of the present invention as defined in the appended claims. For example, utilizing AZO layer for back electric contact layer is illustrated as an example. Other transparent conductive layer that can be tuned in one way or other to change anode-absorber interface internal electric field and subsequently the carrier collection at the back electric contact for improving photo-electric conversion efficiency. Due to the nature of bifacial photovoltaic cell, it is important to have a control of the interface internal electric field by one or more material or structural parameters to enhance charge separation and improve carrier collection efficiency at both front and back electrode of the cell. Additionally, although the above embodiments described have been applied to absorber made by CdTe, or CIS and/or CIGS and capped by AZO layer for front and back electric contact in a film stack, other thin film based bifacial solar cell with single, double, or more junctions, certainly can also be benefited from the embodiments, without departing from the invention described by the claims herein.

What is claimed is:

1. A method for forming a bifacial thin film photovoltaic cell, the method comprising:
providing a glass substrate having a surface region covered by an intermediate layer;
forming a thin film photovoltaic cell on the surface region, the thin film photovoltaic cell comprising an anode overlying the intermediate layer, an absorber over the anode, and a window layer and cathode over the absorber mediated by a buffer layer;
wherein the anode comprises an aluminum doped zinc oxide (AZO) layer forming a first interface with the intermediate layer and a second interface with the absorber, the AZO layer is configured to induce Fermi level pinning at the first interface and a strain field from the first interface to the second interface.

2. The method of claim 1 wherein the intermediate layer comprises a film made by material selected from fluorine doped tin oxide (TFO), indium tin oxide (ITO), Si₃N₄, SiO₂, molybdenum, and combinations thereof.

3. The method of claim 1 wherein the absorber comprises a p-type semiconductor layer made by CdTe material or copper indium gallium diselenide CIGS material.

4. The method of claim 1 wherein the AZO layer comprises a heavily doped Al species ranging from 5×10¹⁹ cm⁻³ to 1×10²¹ cm⁻³.

5. The method of claim 1 wherein both the Fermi level pinning at the first interface and the strain field from the first interface to the second interface cause a reduction in internal electric field strength at the second interface.

6. The method of claim 5 wherein the reduction in internal electric field strength at the second interface reduce a barrier for hole tunneling across the second interface from the absorber to the anode.

7. The method of claim 1 wherein both the Fermi level pinning at the first interface and the strain field from the first interface to the second interface cause a flipping in internal electric field direction at the second interface.

8. The method of claim 7 wherein the flipping in electric internal field direction at the second interface directly aids a collection of holes at the second interface from the absorber to the anode.

9. The method of claim 1 wherein the substrate comprises soda lime glass.

10. The method of claim 1 wherein the substrate comprises an optically transparent material.

11. A thin film solar device utilizing a strained AZO layer for anode-absorber interface, the device comprising:
an optically transparent substrate;
an intermediate layer overlying the transparent substrate;
an anode layer comprising an aluminum doped zinc oxide (AZO) layer forming a first interface with the intermediate layer;
an absorber comprising copper indium gallium diselenide with p-type dopant forming a second interface with the AZO layer;
a buffer layer followed by a window layer overlying the absorber; and
a cathode layer overlying the window layer;
wherein the AZO layer induces a strain field in the anode layer and Fermi level pinning at the first interface for changing internal electric field at the second interface.

12. The device of claim 11 wherein the optically transparent substrate comprises soda lime glass.

13. The device of claim 11 wherein the intermediate layer comprises a film made by material selected from fluorine doped tin oxide (TFO), indium tin oxide (ITO), Si₃N₄, SiO₂, molybdenum, and combination thereof.

14. The device of claim 11 wherein the AZO layer comprises a heavily doped Al species ranging from 5×10¹⁹ cm⁻³ to 1×10²¹ cm⁻³.

15. The device of claim 11 wherein the strain field in the anode layer and Fermi level pinning at the first interface causes a reduction of the internal electric field strength at the second interface for facilitating hole collection by the anode layer from the absorber.

16. The device of claim 11 wherein the strain field in the anode layer and Fermi level pinning at the first interface causes a flipping of internal electric field direction at the second interface for facilitating hole collection by the anode layer from the absorber.

17. The device of claim 11 wherein the buffer layer comprises cadmium sulfide with n-type dopant.

18. The device of claim 11 wherein the window layer comprises a transparent conductive oxide including aluminum doped zinc oxide.

19. The device of claim 11 wherein the cathode layer comprises heavily aluminum doped zinc oxide.

20. The device of claim 11 wherein the absorber comprises cadmium telluride with p-type dopant
